(19) United States
(12) Patent Application Publication
(10) Pub. No.: US 2022/0379355 A1
(43) Pub. Date: Dec. 1, 2022

(54) APPARATUS FOR TREATING SUBSTRATE

(71) Applicant: SEMES CO., LTD., Cheonan-si (KR)

(72) Inventors: Ye Jin CHOI, Seoul (KR); Cheol Hwan JEONG, Pyeongtaek-si (KR); Young Jin KIM, Cheonan-si (KR); Jong Won MOON, Cheonan-si (KR)

(73) Assignee: SEMES CO., LTD., Cheonan-si (KR)

(21) Appl. No.: 17/824,169

(22) Filed: May 25, 2022

(30) Foreign Application Priority Data
May 26, 2021 (KR) 10-2021-0067346

(51) Int. Cl. B08B 13/00; B08B 3/02

(52) U.S. Cl. CPC B08B 13/00; B08B 3/022

(57) ABSTRACT

The inventive concept provides a substrate treating apparatus. The substrate treating apparatus includes a treating container having a treating space; a support unit configured to support and rotate a substrate in the treating space; an exhaust line coupled to the treating container and configured to exhaust an airflow within the treating space; a support frame provided independently of a rotation of the support unit and positioned between the treating container and the support unit; and a guide vane protruding to an outside of the support frame and configured to guide the airflow within the treating space in a downward direction.

### CROSS-REFERENCE TO RELATED APPLICATIONS

This application claims priority under 35 U.S.C. § 119 to Korean Patent Application No. 10-2021-0067346 filed on May 26, 2021, in the Korean Intellectual Property Office, the disclosures of which are incorporated by reference herein in their entireties.

### TECHNICAL FIELD

Embodiments of the inventive concept described herein relate to a substrate treating apparatus, and more specifically, to a substrate treating apparatus for treating a substrate by rotating the substrate and supplying a liquid onto the substrate.

### BACKGROUND

Various processes such as a photolithography process, a thin film deposition process, an ashing process, an etching process, and an ion implantation process are carried out to manufacture a semiconductor device. Also, a cleaning process for a cleaning treatment of remaining particles on the substrate is performed before and after each of the processes is performed. The substrate treating process is performed with various liquid at the cleaning process of the substrate.

The cleaning process includes a process of supplying a chemical to the substrate supported and rotated by a spin head, a process of removing the chemical from the substrate by supplying a cleaning liquid such as a deionized water (DIW) to the substrate, and afterwards, a process of replacing the cleaning liquid on the substrate with an organic solvent by supplying an organic solvent such as an isopropyl alcohol (IPA) solution having a bottom surface tension than the cleaning solution, and a process of removing the substituted organic solvent from the substrate.

FIG. 1 illustrates a conventional substrate treating apparatus. Referring to FIG. 1, the substrate treating apparatus 1000 disposes the substrate W on the support unit 1200 within a treating container 1300 having a treating space, and treats the substrate W while supplying a liquid to a rotating substrate W. When treating the substrate W, a fan filter unit provided on a top side of a housing 1100 supplies a downward airflow to an inside of the treating space. The by-products such as a gas generated during a treating of the substrate are discharged to an outside through an exhaust line 1400 provided on a bottom side of the treating container 1300 together with the downward airflow. When an inner pressure of the treating space is maintained at a set pressure, a smooth exhaust is performed through the exhaust line 1400.

In the cleaning process, the substrate is treated while supplying the liquid onto the substrate W rotated by the support unit 1200. As the support unit 1200 rotates, a rotational airflow is generated within the treating space. As illustrated in FIG. 2, as the rotational airflow is formed, the downward airflow provided by the fan filter unit to the treating space does not reach the exhaust line 1400, and an airflow stagnation occurs at a side surface of the support unit 1200. For this reason, it is difficult to maintain a pressure within the treating space at the set pressure. Particularly, when the support unit 1200 rotates at a high speed and performs a liquid treatment on the substrate W, the rotational airflow formed within the treating space becomes stronger. Since the inner pressure of the treating space is converted to a pressure higher than the set pressure, it is difficult to exhaust the treating space through the exhaust line 1400. For this reason, the liquid supplied onto the substrate W in the treating space returns onto the substrate W or flows backwardly. In addition, as an exhaust does not proceed, a particle, a fume, and the like generated during the treating process are scattered in the treating space.

### SUMMARY

Embodiments of the inventive concept provide a substrate treating apparatus capable of relieving an airflow stagnation within a treating space due to a rotational airflow formed by a rotation of the support unit, when treating a substrate while rotating the substrate in the treating space.

Embodiments of the inventive concept provide a substrate treating apparatus capable of maintaining an inner pressure of a treating space to a set pressure, when treating a substrate while rotating the substrate in the treating space.

Embodiments of the inventive concept provide a substrate treating apparatus capable of stably performing an exhaust of an inside of a treating space, when treating a substrate while rotating the substrate in the treating space.

Embodiments of the inventive concept provide a substrate treating apparatus capable preventing a formation of a particle on a substrate, when treating the substrate while rotating the substrate in the treating space.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a treating container having a treating space; a support unit configured to support and rotate a substrate in the treating space; an exhaust line coupled to the treating container to exhaust an airflow within the treating space; a support frame provided independently of a rotation of the support unit and positioned between the treating container and the support unit; and a guide vane protruding to an outside of the support frame and configured to guide the airflow within the treating space in a downward direction.

In an embodiment, the support unit includes a spin chuck supporting the substrate; a rotation shaft coupled to a bottom surface of the spin chuck and configured to rotate the spin chuck; and a first driver configured to provide a rotational force to the rotation shaft, and wherein the support frame has a ring shape to surround an outer circumferential surface of the rotation shaft.

In an embodiment, the guide vane includes a longitudinally extending portion defining a substantially 90 degrees included angle with a top surface of the spin chuck.

In an embodiment, the guide vane includes a longitudinally extending portion defining an obtuse included angle with a top surface of the spin chuck.

In an embodiment, the guide vane is provided in a plurality along on an outer circumferential surface of the support frame, and each of the plurality of the guide vanes includes a longitudinally extending portion, at least two of the plurality of the guide vanes having different included angles with a top surface of the spin chuck each other.

In an embodiment, the guide vane further includes a transversely extending portion from the longitudinally extending portion along a top surface of the support frame, the transversely extending portion has a top surface lower than the bottom surface of the spin chuck.

In an embodiment, the guide vane further includes a transversely extending portion from the longitudinally extending portion along a top surface of the support frame, the transversely extending portion has a top surface lower than the top surface of the spin chuck and higher than the bottom surface of the spin chuck.

In an embodiment, the support frame is stationary within the treating container.

In an embodiment, the support frame further includes a second driver configured to rotate the support frame independently of the rotation of the support unit, and wherein the second driver rotates the support frame in the same direction with and at a lower speed than of the support unit.

In an embodiment, the support frame further includes a second driver configured to rotate the support frame independently of the rotation of the support unit, and wherein the second driver rotates the support frame in the opposite direction to the support unit.

In an embodiment, the support frame further includes an annular ring body adjacent a bottom of the spin chuck and having substantially planar top and bottom surfaces, and wherein the guide vane includes a first portion transversely extending along the top surface of annular ring body and a second portion longitudinally extending from the first portion at least along outer sidewall of the annular ring body.

In an embodiment, the substrate treating apparatus further includes a rear nozzle on the top surface of the annular ring body to discharge a liquid to the spin chuck.

The inventive concept provides a substrate treating apparatus. The substrate treating apparatus includes a treating container having a treating space; a support unit configured to support and rotate a substrate in the treating space; an exhaust line coupled to the treating container to exhaust an airflow within the treating space; and a guide vane configured to guide an airflow within the treating space in a downward direction.

In an embodiment, the guide vane extends longitudinally in parallel with a rotation axis of the support unit.

In an embodiment, the guide vane extends longitudinally with defining an acute included angle with a rotation axis of the support unit.

In an embodiment, the substrate treating apparatus further includes a support frame provided independently of the rotation of the support unit and surrounding the support unit, and wherein the guide vane is mounted on the support frame.

In an embodiment, the guide vane is installed on an inner wall of the treating container.

The inventive concept provides a substrate treating apparatus. The substrate treating apparatus includes a housing having an inner space; a treating container disposed within the inner space and having a treating space; a support unit configured to support and rotate a substrate in the treating space; a liquid supply unit configured to supply a liquid to the substrate supported by the support unit; an airflow supply unit forming an airflow in the treating space; an exhaust line coupled to the treating container to exhaust an airflow within the treating space; a stationary support frame surrounding the support unit; and a guide vane installed on the support frame and configured to guide the airflow within the treating space in a downward direction.

In an embodiment, the guide vane extends downwardly in substantially parallel with a rotation axis of the support unit.

In an embodiment, the guide vane extends downwardly with defining an acute included angle with a rotation axis of the support unit.

According to an embodiment of the inventive concept, an airflow stagnation within a treating space may be relieved by guiding a rotational airflow formed by a rotation of the support unit downwardly, when treating a substrate while rotating the substrate in the treating space.

According to an embodiment of the inventive concept, a set pressure of an inner pressure of a treating space may be maintained, when treating a substrate while rotating the substrate in the treating space.

According to an embodiment of the inventive concept, an exhaust of an inside of a treating space may be stably maintained, when treating a substrate while rotating the substrate in the treating space.

According to an embodiment of the inventive concept, a formation of a particle on a substrate may be prevented, when treating the substrate while rotating the substrate in the treating space.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a cross-sectional view schematically illustrating a conventional substrate treating apparatus.

FIG. 2 schematically illustrates an airflow stagnation by a rotational airflow in the conventional substrate treating apparatus of FIG. 1.

FIG. 3 schematically illustrates an embodiment of the substrate treating apparatus of the inventive concept.

FIG. 4 schematically illustrates an embodiment of a process chamber of the substrate treating apparatus of FIG. 3.

FIG. 5 schematically illustrates a cut view of the substrate treating apparatus of FIG. 4.

FIG. 6 schematically illustrates a perspective view of a guide vane of FIG. 3.

FIG. 7 schematically illustrates an airflow in the process chamber of FIG. 4.

FIG. 8 is a cut perspective view schematically illustrating the airflow within the treating container of FIG. 4.

FIG. 9 schematically illustrates an inner pressure of the process chamber of FIG. 4.

FIG. 10 schematically illustrates another embodiment of the process chamber of the substrate treating apparatus of FIG. 4.

FIG. 11 schematically illustrates a perspective view of the guide vane of FIG. 10.

FIG. 12 to FIG. 14 schematically illustrate another embodiment of the guide vane of FIG. 4.

FIG. 15 to FIG. 16 schematically illustrate another embodiment of the process chamber of the substrate treating apparatus of FIG. 4.

FIG. 17 to FIG. 18 schematically illustrate another embodiment of the process chamber of the substrate treating apparatus of FIG. 4.

FIG. 19 schematically illustrates another embodiment of the process chamber of the substrate treating apparatus of FIG. 4.

FIG. 20 is a cutting perspective view schematically illustrating the airflow in the treating container of FIG. 19.

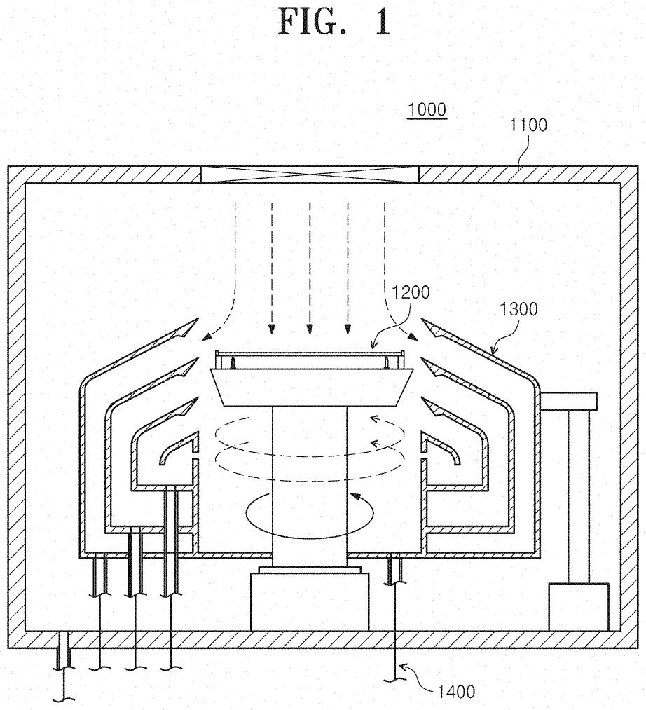

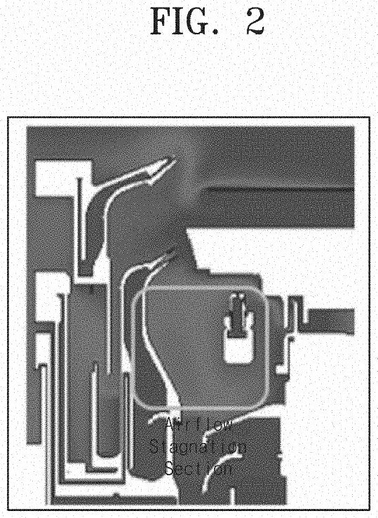

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. The embodiment is provided to more fully explain the inventive concept to a person with average knowledge in the art. Therefore, the form of the components in the drawings is exaggerated to emphasize a clearer description.

It should be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

In the embodiment, a process of liquid treating a substrate by supplying a liquid such as a cleaning liquid onto the substrate will be described as an example. However, the embodiment is not limited to a cleaning process, and may be applied to various processes for treating the substrate using a treating liquid such as an etching process, an ashing process, a developing process, and the like.

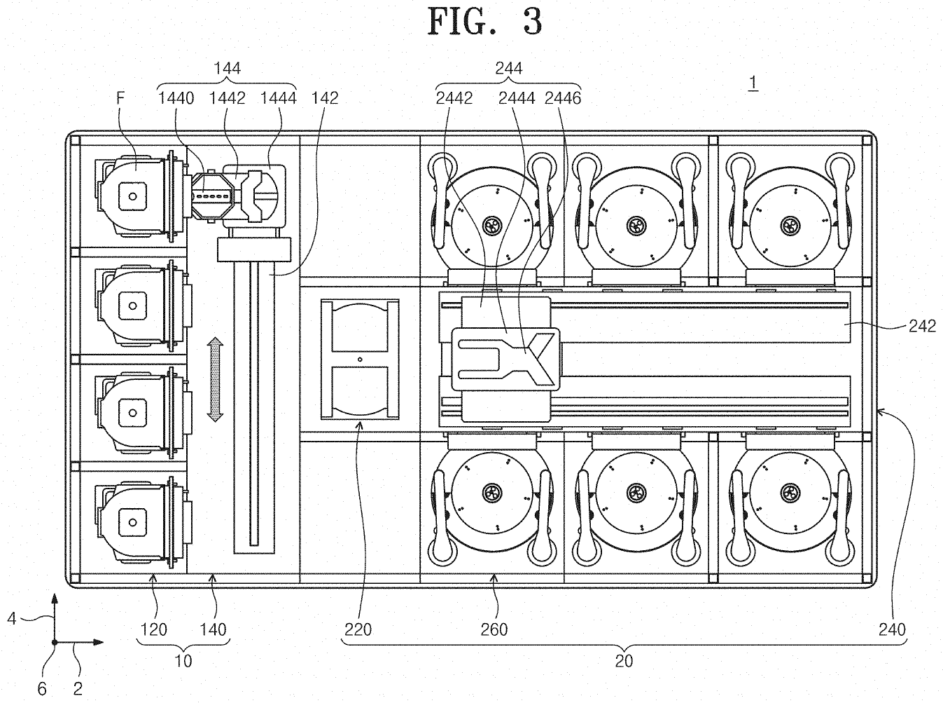

Hereinafter, an embodiment of the inventive concept will be described in detail with reference to FIG. 3 to FIG. 18.

FIG. 3 schematically illustrates a substrate treating apparatus according to an embodiment of the inventive concept. Referring to FIG. 3, the substrate treating apparatus 1 includes an index module 10 and a treating module 20. According to an embodiment, the index module 10 and the treating module 20 are disposed in a direction. Hereinafter, a direction in which the index module 10 and the treating module 20 are disposed is referred to as a first direction 2, a direction perpendicular to the first direction 2 when seen from above is referred to as a second direction 4, and a direction perpendicular to a plane including both the first direction 2 and the second direction 4 is defined as a third direction 6.

The index module 10 transfers the substrate W from a container F in which the substrate W is stored to the treating module 20 that treats the substrate W. The index module 10 receives the substrate W that has been treated at the treating module 20 and stores the substrate W at the container F. A lengthwise direction of the index module 10 is provided in the second direction 4. The index module 10 has a load port 120 and an index frame 140.

The container F in which the substrate W is stored is mounted on the load port 120. The load port 110 and the treating module 300 are disposed on two opposite sides of the index frame 140. The load port 120 may be provided in a plurality, and the plurality of load ports 120 may be arranged in a row along the second direction 4. A number of load ports 120 may increase or decrease according to a process efficiency and a foot print condition of the treating module 20.

A plurality of slots (not shown) are formed at the container F to store the substrates W in a state in which the substrates W are horizontally arranged with respect to the ground. As the container F, a sealed container such as a front opening unified pod (FOUP) may be used. The container F may be placed on the load port 120 by a transfer means (not shown) such as an overhead transfer, an overhead conveyor, or an automatic guided vehicle, or by an operator.

An index rail 142 and an index robot 144 are provided within the index frame 140. The index rail 142 is provided with its lengthwise direction along the second direction 4 within the index frame 140. The index robot 144 may transfer the substrate W. The index robot 144 may transfer the substrate W between the index module 10 and the buffer unit 220. The index robot 144 may include an index hand 1440. The substrate W may be placed on the index hand 1440. The index hand 1440 may include an index base 1442 having an annular ring form in which a part of the circumference is symmetrically cut-out, and an index support unit 1444 for moving the index base 1442. A configuration of the index hand 1440 is the same as or similar to a configuration of a transfer hand to be described later. The index hand 1440 may be provided to be movable along the second direction 4 along the index rail 142. Accordingly, the index hand 1440 may forwardly and backwardly move along the index rail 142. In addition, the index hand 1440 may be provided to be rotatable with the third direction 6 as an axis, and movable along the third direction 6.

The treating module 20 includes a buffer unit 220, a transfer chamber 240, and a process chamber 260. The buffer unit 220 provides a space in which a substrate W taken into the treating module 20 and a substrate W taken out from the treating module 20 temporarily remain. The transfer chamber 240 provides a space for transferring the substrate W between the buffer unit 220 and the process chamber 260 and between the process chambers 260. The process chamber 260 may perform a liquid treating process of treating the substrate W by supplying a liquid onto the substrate W. For example, the liquid treating process may be a cleaning process of cleaning the substrate with a cleaning liquid. A chemical treatment, a rinsing treatment, and a drying treatment may all be performed on the substrate within the process chamber. Optionally, a process chamber for drying the substrate may be provided separately from a process chamber for performing a liquid treatment.

The buffer unit 220 may be disposed between the index frame 140 and the transfer chamber 240. The buffer unit 220 may be located at an end of the transfer chamber 240. A slot (not shown) on which the substrate W is placed is provided inside the buffer unit 220. A plurality of slots (not shown) are provided to be spaced apart from each other along the third direction 6. A front face and a rear face of the buffer unit 220 are opened. The front face is a surface facing the index module 10, and the rear face is a surface facing the transfer chamber 240. The index robot 144 may access the buffer unit 220 through the front face, and the transfer robot 244, which will be described later, may access the buffer unit 220 through the rear face.

A lengthwise direction of the transfer chamber 240 may be provided in the first direction 2. Each of the process chambers 260 may be disposed on both sides of the transfer chamber 240. The process chamber 260 may be disposed at a side of the transfer chamber 240. The process chamber 260 and the transfer chamber 240 may be disposed along the second direction 4. According to an embodiment, the process chambers 260 may be disposed on both sides of the transfer chamber 240, and the process chambers 260 may be provided in an array of A×B (A and B are natural numbers greater than 1 or 1) along the first direction 2 and the third direction 6, respectively. Here, A is a number of process chambers 260 provided in a row along the first direction 2, and B is the number of process chambers 260 provided in a row along the third direction 6. When four or six process chambers 260 are provided at a side of the transfer chamber 240, the process chambers 260 may be arranged in an array of 2×2 or 3×2. A number of the process chambers 260 may increase or decrease. Unlike the above, the process chamber 260 may be provided only at a side of the transfer chamber 240. In addition, the process chamber 260 may be provided as a single layer at a side and at both sides of the transfer chamber 240.

The transfer chamber 240 includes a guide rail 242 and a transfer robot 244. The guide rail 242 is provided with its lengthwise direction in the first direction 2 within the transfer chamber 240. The transfer robot 244 may be provided to be linearly movable along the first direction 2 on the guide rail 242. The transfer robot 244 transfers the substrate W between the buffer unit 220 and the process chamber 260 and between the process chambers 260.

The transfer robot 2440 includes a base 2442, a body 2444, and an arm 2446. The base 2442 is installed to be movable in the first direction 2 along the guide rail 242. The body 2444 is coupled to the base 2442. The body 2444 is provided to be movable along the third direction 6 on the base 2442. In addition, the body 2444 is provided to be rotatable on the base 2442. The arm 2446 is coupled to the body 2444, which is provided to be forwardly and backwardly movable with respect to the body 2444. The arm 2446 is provided in a plurality to be driven individually, respectively. The arms 2446 are disposed to be stacked on each other and spaced apart from each other along the third direction 6.

The process chamber 260 performs a liquid treating process on the substrate W. For example, the process chamber 260 may be a chamber that performs a cleaning process by supplying the cleaning liquid to the substrate W. Unlike this, the process chamber 260 may be a chamber that performs a wet etching process of removing a thin film on the substrate by supplying a liquid plasma. The process chamber 260 may have a different structure depending on a type of a process for treating the substrate W. Alternatively, each of the process chambers 260 may have a same structure. Selectively, the process chambers 260 may be divided into a plurality of groups, and the process chambers 260 belonging to one of the groups may be process chambers 260 performing any one of the cleaning process and the wet etching process, and process chambers 260 belong to another one of the groups may be process chambers 260 performing any one of the cleaning process and the wet etching process.

In the following embodiment of the inventive concept, a case where the liquid treating process of treating the substrate W by supplying a liquid onto the substrate W from the process chamber 260 will be described as an example.

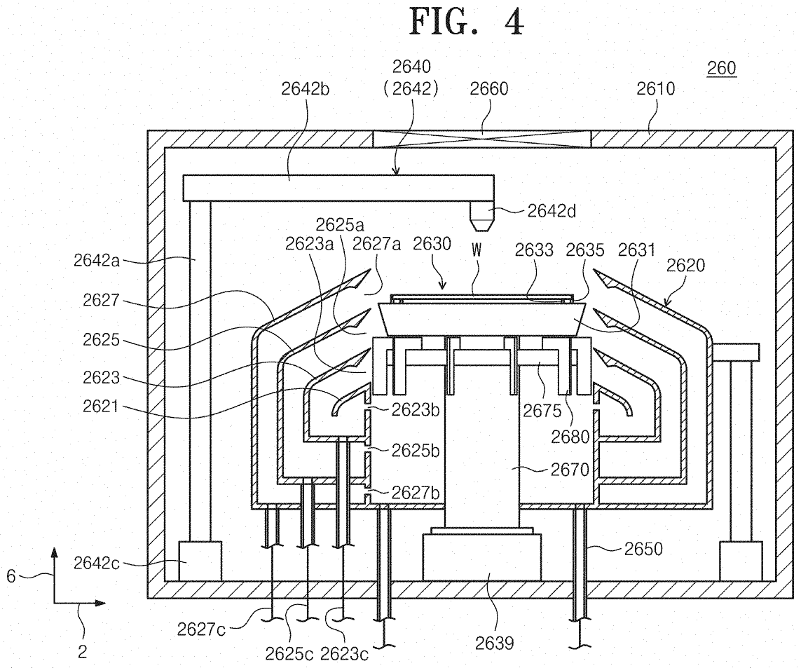

FIG. 4 schematically illustrates an embodiment of the process chamber. Referring to FIG. 4, the process chamber 260 includes a housing 2610, a treating container 2620, a support unit 2630, a liquid supply unit 2640, an exhaust line 2650, an airflow supply unit 2660, a support frame 2670, and a guide vane 2680.

The housing 2610 has a space therein. The housing 2610 has generally a rectangular parallelepiped form. The treating container 2620, the support unit 2630, and the liquid supply unit 2640 are disposed within the housing 2610.

The treating container 2620 has a treating space with an open top. The substrate W is liquid-treated within the treating space. The support unit 2630 supports the substrate W in the treating space and rotates the substrate W. The liquid supply unit 2640 supplies a liquid onto the substrate W supported by the support unit 2630. The liquid may be provided in a plurality of types and may be sequentially supplied onto the substrate W.

According to an embodiment, the treating container 2620 has a guide wall 2621 and a plurality of recollecting containers 2623, 2625, and 2627. Each of the recollecting containers 2623, 2625, and 2627 separates and recollects different liquids from the liquids used for the substrate treatment. Each of the recollecting containers 2623, 2625, and 2627 has a recollecting space for recollecting the liquid used for the substrate treatment. The guide wall 2621 and each of the recollecting containers 2623, 2625, and 2627 are provided in an annular ring form surrounding the support unit 2630. When the liquid treating process is performed, a liquid scattered by the rotation of the substrate W is introduced into the recollecting space through inlets 2623a, 2625a, and 2627a to be described later of the recollecting containers 2623, 2625, and 2627 respectively. Different types of the treating liquid may flow into each recollecting container.

According to an embodiment, the treating container 2620 has the guide wall 2621, the first recollecting container 2623, the second recollecting container 2625 and the third recollecting container 2627. The guide wall 2621 is provided in an annular ring form surrounding the support unit 2630, and the first recollecting container 2623 is provided in an annular ring form surrounding the guide wall 2621. The second recollecting container 2625 is provided in an annular ring form surrounding the first recollecting container 2623, and the third recollecting container 2627 is provided in an annular ring form surrounding the second recollecting container 2625. A space between the first recollecting container 2623 and the guide wall 2621 functions as a first inlet 2623a through which a liquid is introduced. A space between the first recollecting container 2623 and the second recollecting container 2625 functions as a second inlet 2625a through which a liquid is introduced. A space between the second recollecting container 2625 and the third recollecting container 2627 functions as a third inlet 2627a through which a liquid is introduced. The second inlet 2625a is positioned above the first inlet 2623a, and the third inlet 2627a can be positioned above the second inlet 2625a.

A space between a lower end of the guide wall 2621 and the first recollecting container 2623 functions as a first outlet 2623b through which a fume and an airflow generated from the liquid are discharged. A space between a lower end of the first recollecting container 2623 and the second recollecting container 2625 functions as a second outlet 2625b through which the fume and the airflow generated from the liquid are discharged. A space between a lower end of the second recollecting container 2625 and the third recollecting container 2627 functions as a third outlet 2627b through which the fume and the airflow generated from the liquid are discharged. The fume and the airflow discharged from the first outlet 2623b, the second outlet 2625b, and the third outlet 2627b are exhausted through an exhaust unit 2650 to be described later.

The recollecting lines 2623c, 2625c, 2627c extending vertically in a bottom direction of a bottom surface are connected to each recollecting container 2623, 2625, 2627. Each of the recollecting lines 2623c, 2625c, and 2627c discharges the treating liquid introduced through each of the recollecting containers 2623, 2625, and 2627. A discharged treating liquid may be reused through an external treating liquid regeneration system (not shown).

The support unit 2630 has a spin chuck 2631, a support pin 2633, a chuck pin 2635, a rotation shaft 2637, and a first driver 2639. The spin chuck 2631 has a top surface, which is generally a circular form when viewed from above. The top surface of the spin chuck 2631 may have a diameter larger than that of the substrate W.

The support pin 2633 may be provided in a plurality. The support pins 2633 are disposed at an edge portion of the top surface of the spin chuck 2631 to be spaced apart from each other at a predetermined interval with defining an annular ring, and upwardly protrude from the spin chuck 2631. The support pins 2633 support an edge of rear surface of the substrate W such that the substrate W is spaced apart from the top surface of the spin chuck 2631 by a predetermined distance.

The chuck pin 2635 may be provided in a plurality. The chuck pins 2635 are disposed to be farther from a center of the spin chuck 2631 than the support pin 2633. The chuck pins 2635 protrude from the top surface of the spin chuck 2631. The chuck pins 2635 support a side portion of the substrate W so that the substrate W does not laterally shift or sway when the substrate W is rotated. The chuck pins 2635 are movable between a standby position and a support position along a radial direction of the spin chuck 2631. The standby position is a position far from the center of the spin chuck 2631 compared to the support position. When the substrate W is loaded or unloaded on the support unit 2630, the chuck pin 2635 is positioned at the standby position, and when a process is performed on the substrate W, the chuck pin 2635 is positioned at the support position to support the substrate W and to block lateral shifting or swaying of the substrate W. At the support position, the chuck pins 2635 are in contact with the side of the substrate W.

The rotation shaft 2637 is coupled to the spin chuck 2631. The rotation shaft 2637 may be coupled to a bottom surface of the spin chuck 2631. The rotation shaft 2637 is provided to be rotatable by receiving a power from the first driver 2639. The first driver 2639 rotates the rotation shaft 2637, thereby rotating the spin chuck 2631. The first driver 2639 may vary a rotation speed of the rotation shaft 2637. The first driver 2639 may be a motor that provides a driving force. However, the inventive concept is not limited thereto, and may be variously modified as a known device that provides a driving force.

The liquid supply unit 2640 supplies a liquid onto the substrate W supported by the support unit 2630. The liquid supply unit 2640 is provided in a plurality, and each supplies a different type of liquid. According to an embodiment, the liquid supply unit 2640 includes a first liquid supply member 2642.

The first liquid supply member 2642 includes a support shaft 2642a, a support arm 2642b, an arm driver 2642c, and a nozzle 2642d. The support shaft 2642a is located near the sidewall of the treating container 2620. The support shaft 2642a has a rod shape extending vertically. The support shaft 2642a is provided to be rotatable by the arm driver 2642c. The support arm 2642b is coupled to a top end of the support shaft 2642a. The support arm 2642b extends horizontally from the support shaft 2642a. The nozzle 2642d is fixedly coupled to an end of the support arm 2642b. As the support shaft 2642a is rotated, the nozzle 2642d may swing together with the support arm 2642b. The nozzle 2642d may be swing-moved to a process position and a standby position. Here, the process position is a position where the nozzle 2642d faces the substrate W supported by the support unit 2630, and the standby position is a position where the nozzle 2642d is out of the process position.

In some embodiments, the support arm 2642b may be provided to be forwardly and backwardly movable in its lengthwise direction. When viewed from above, the nozzle 2642d may be swing-moved to coincide with a central axis of the substrate W.

The first treating liquid and the second treating liquid may be any one of a chemical, a rinsing liquid, or an organic solvent. For example, the chemical may include a diluted sulfuric acid peroxide (H₂SO₄), a phosphoric acid (P₂O₅), a hydrofluoric acid (HF), and an ammonium hydroxide (NH₄OH). For example, the rinsing solution may include a water or a deionized water (DIW). For example, the organic solvent may include an alcohol such as an isopropyl alcohol (IPA).

The exhaust line 2650 exhausts the fume and the gas generated in the treating space. The exhaust line 2650 exhausts the fume and the gas generated when the substrate W is liquid-treated. The exhaust line 2650 may be coupled to a bottom surface of the treating container 2620. In an embodiment, the exhaust line 2650 may be positioned between the rotation shaft 2637 of the support unit 2630 and an inner wall of the treating container 2620. A decompression unit (not shown) is provided at the exhaust line 2650. The fume and the gas generated during a liquid treatment of the substrate W by the decompression unit are exhausted from the treating space to an outside of the treating space.

The airflow supply unit 2660 supplies an airflow to the inner space of the housing 2610. The airflow supply unit 2660 may supply a downward airflow to the inner space. The airflow supply unit 2660 may be installed at the housing 2610. The airflow supply unit 2660 may be installed above the treating container 2620 and the support unit 2630. A gas supplied to the inner space of the housing 2610 through the airflow supply unit 2660 forms a downward airflow in the inner space. The gas by-products generated by the treating process within the treating space are discharged to an outside of the housing 2610 through the exhaust line 2650 by the downward airflow. The airflow supply unit 2660 may be provided as a fan filter unit.

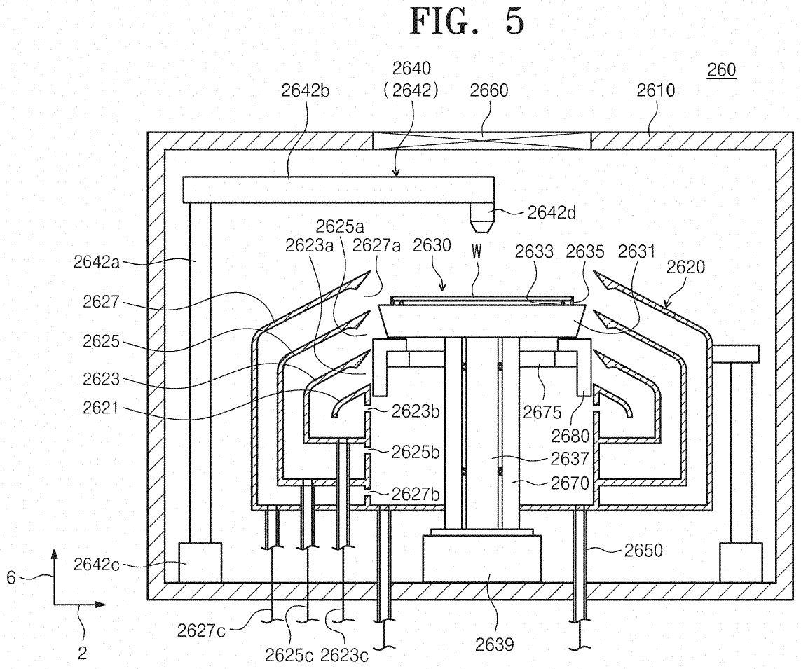

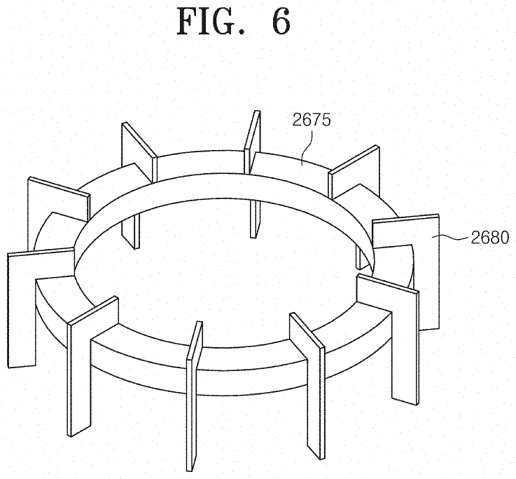

FIG. 5 schematically illustrates a cut surface of the substrate treating apparatus of FIG. 4. FIG. 6 schematically illustrates a perspective view of the guide vane of FIG. 4. Hereinafter, a support frame and a guide vane according to an embodiment of the inventive concept will be described with reference to FIG. 4 to FIG. 6.

Referring to FIG. 4 and FIG. 5, the support frame 2670 is positioned between treating container 2620 and the support unit 2630. The support frame 2670 may be provided to surround an outer circumferential surface of the rotation shaft 2637 of the support unit 2630. The support frame 2670 may have a ring shape surrounding the outer circumferential surface of the rotation shaft 2637. The support frame 2670 is provided independently of a rotation of the support unit 2630. For example, a bearing may be provided between an inner sidewall (e.g., inner circumferential surface) of the support frame 2670 and the outer circumferential surface of the rotation shaft 2637. Accordingly, the support frame 2670 may keep stationary during the rotation of the support unit 2630. During treating process, while not rotating the support frame 2670 may support the bottom of the rotating support unit 2630. The guide vane 2680 may be installed on the support frame 2670, for example at least on outer sidewall of the support frame 2670 near the support unit 2630.

The support frame 2670 may include a body portion 2675 having an annular ring shape to surround the outer sidewall (e.g., outer circumferential surface) of the support frame 2670. The body portion 2675 may be provided at a position adjacent to the bottom end of the support unit 2630. The body portion 2675 may be fixedly provided.

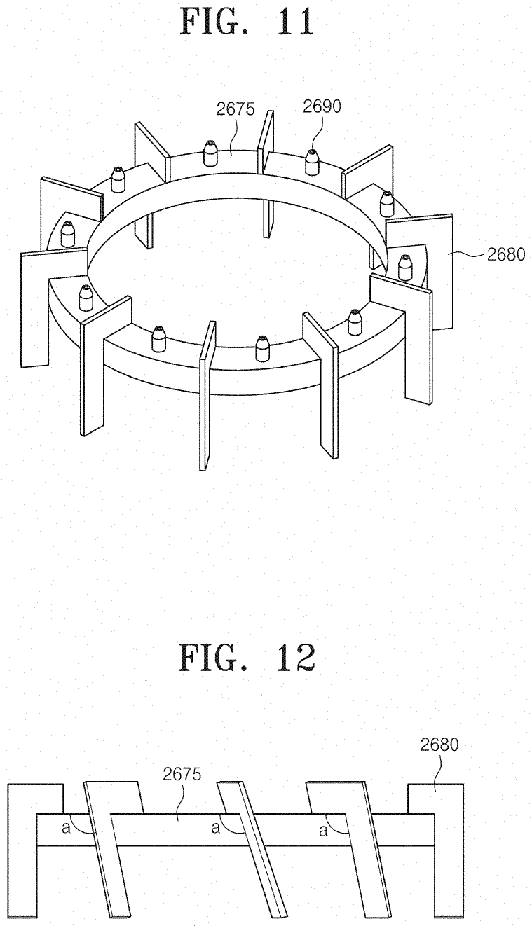

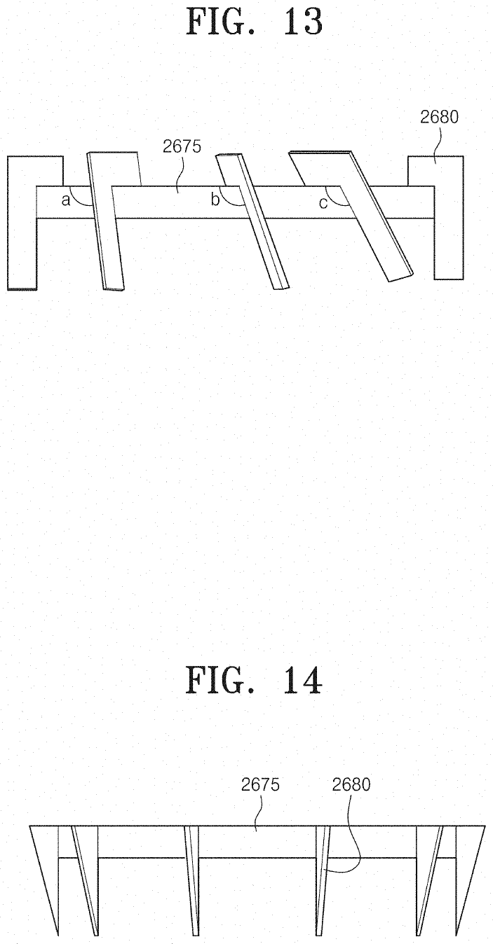

The guide vane 2680 is mounted on the body portion 2675. The guide vane 2680 is indirectly mounted on the support frame 2670 via the body portion 2675. Since the support frame 2670 is provided to be stationary, thereby the body portion 2675 being stationary, the guide vane 2680 is also provided to stationary. The guide vane 2680 may protrude to an outside of the body portion 2675 and extend downwardly. In an embodiment, the guide vane 2680 is mounted on the top surface of the body portion 2675 and extends downwardly along the outer sidewall (outer circumferential surface) of the body portion 2675. For example, in some embodiments, the guide vane 2680 may have a first portion on the top surface of the body 2675 and a second portion at least on the sidewall of the body portion 2675 extending downwardly, thereby the guide vane 2680 having “ ” shape (see FIGS. 12 and 13). In some embodiments, the first portion may be omitted (see FIG. 14) and the second portion extending downwardly may be installed on the sidewall of the body 2675 in various orientations, resulting in a various included angles with the rotation axis of the support unit 2630 (for example, 0 included angle (degree)<90) or with the top surface of the support unit 2630 (for example, 90 included angle (degree)<180).

The guide vane 2680 may be provided in a plurality along a circumferential direction of the outer circumferential surface of the support frame 2670. The plurality of guide vanes 2680 may be provided to be spaced apart from each other at predetermined intervals. In addition, the plurality of guide vanes 2680 may be provided to be spaced apart from each other at different intervals. A top end of the guide vane 2680 (for example, the first portion) may be provided at a position lower than a bottom surface of the spin chuck 2631. A bottom end of the guide vane 2680 (for example the bottom end of the second portion) may be lower than the bottom surface of the body portion 2675.

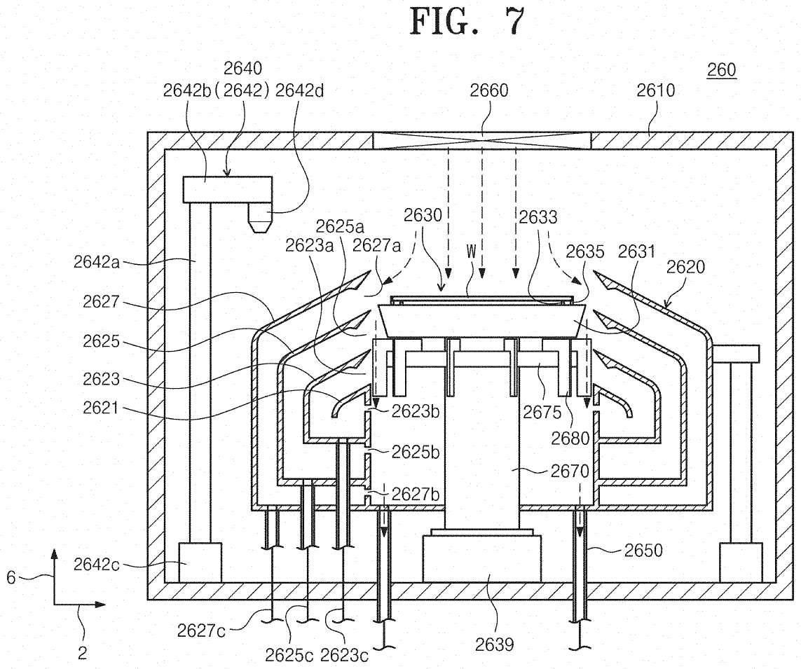

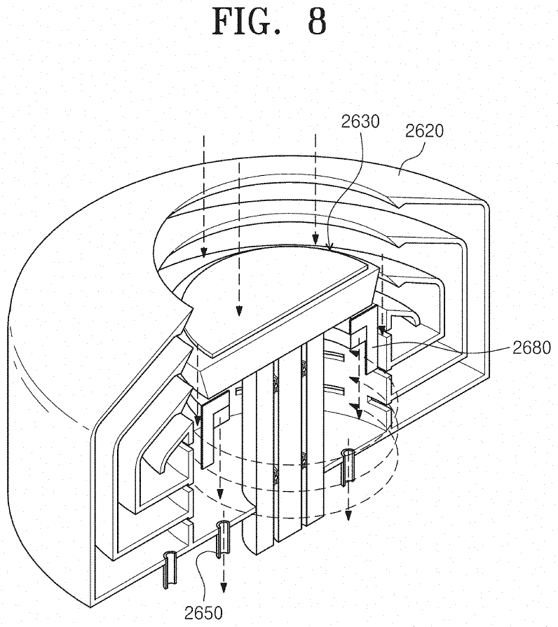

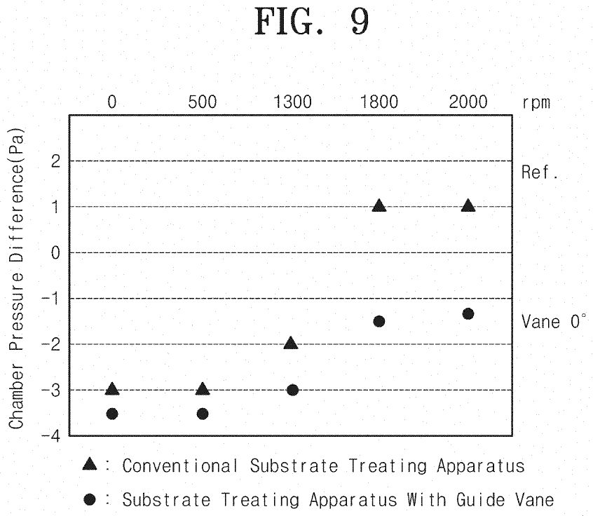

FIG. 7 schematically illustrates an airflow within the process chamber of FIG. 4. FIG. 8 is a cut perspective view schematically illustrating an airflow within the treating container of FIG. 4. FIG. 9 schematically illustrates a pressure within the process chamber of FIG. 4.

Referring to FIG. 7 to FIG. 9, a downward airflow is provided from the airflow supply unit 2650 provided at a top wall of the housing 2610 to the inner space of the housing 2610. When treating the substrate, the spin chuck 2631 rotates, thereby generating a rotational airflow around the rotation axis 2637 in the treating space. The guide vane 2680 is formed perpendicular to the ground (i.e., perpendicular the top surface of the support unit 2630 (the top surface of the spin chuck), parallel with the rotation axis 2637) to guide the rotational airflow in a direction perpendicular to a rotational airflow direction. The top end of the guide vane 2680 is provided at a position lower than the top surface of the spin chuck 2631 in which the rotational airflow is mainly formed, and extends downwardly, thereby downwardly guiding the airflow generated by rotation of the spin chuck 2631. The airflow guided downwardly by the guide vane 2680 may be exhausted by the exhaust line 2660 coupled to the bottom of the treating container.

Accordingly, it is possible to alleviate a generation of a vortex within the treating space due to a rotational airflow generated within the treating space. In addition, it is possible to smoothly exhaust the inside of the treating space by guiding the rotational airflow downwardly. For this reason, it is possible to prevent a pressure within the treating space from being higher than a set pressure due to the rotational airflow within the treating space. Even when the spin chuck 2631 rotates at a high speed and treats the substrate, it is possible to prevent an inner pressure of the treating space from being formed higher than the set pressure. By maintaining the pressure within the treating space at the set pressure, a risk of the liquid supplied to the substrate returning to the substrate and flowing backward may be minimized.

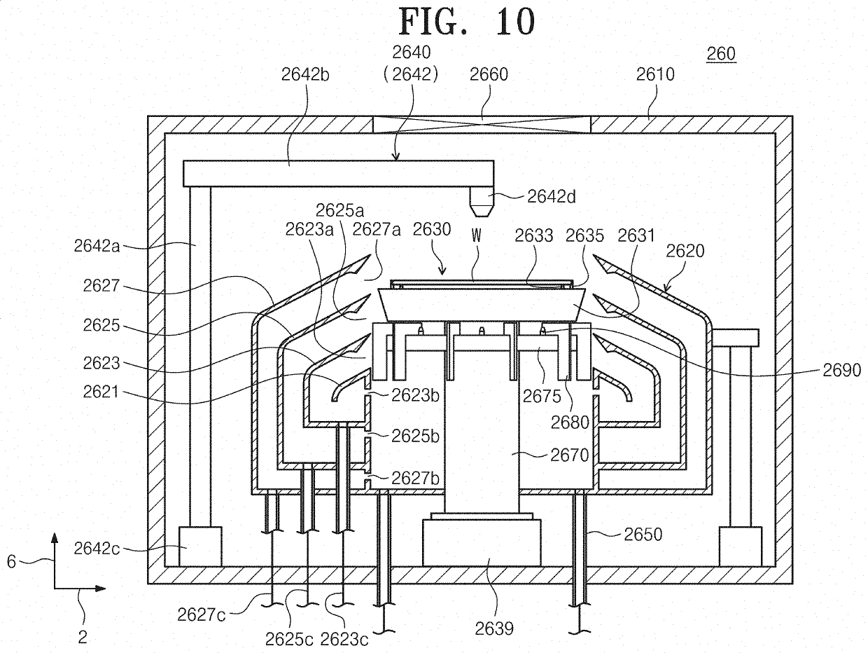

FIG. 10 schematically illustrates another embodiment of the process chamber of the substrate treating apparatus of FIG. 4. FIG. 11 schematically illustrates a perspective view of the guide vane of FIG. 10.

Referring to FIG. 10 to FIG. 11, the substrate treating apparatus 1 may further include a rear nozzle 2690 for discharging a liquid toward the spin chuck 2631. The rear nozzle 2690 may spray the liquid toward the bottom surface of the support unit 2630. The rear nozzle 2690 may be provided on the top surface of the body portion 2675. The rear nozzle 2690 may be positioned between a plurality of guide vanes 2680 (i.e., between first portions thereof) mounted on the top surface of the body portion 2675. The guide vane 2680 and the rear nozzle 2690 are mounted via the body portion 2675 to eliminate a structural complexity of the substrate treating apparatus. A cleaning treatment for the spin chuck 2631 and the treating container 2620 may be provided, and simultaneously, a generation of a vortex due to the rotational airflow within the treating space may be alleviated.

FIG. 12 to FIG. 14 schematically illustrate another embodiment of the guide vane of FIG. 4. Referring to FIG. 12 to FIG. 13, at least some of the guide vanes 2680 may be provided such that a lengthwise direction thereof is inclined with respect to the ground, e.g., some of the guide vane (i.e., the second portion thereof extending downwardly) may have an obtuse included angle with the top surface of the body portion 2675 which is substantially parallel with the top surface of spin chuck 2631). For example, the top end of the guide vane 2680 (e.g., the top end of first portion thereof) may be positioned at an upstream point with respect to a direction in which the spin chuck 2631 rotates, and the bottom end of the guide vane 2680 (e.g., the bottom of the second portion thereof) may be positioned at a downstream point with respect to the direction in which the spin chuck 2631 rotates. An inclination angle (“a”, “b”, “c” in FIG. 13) inclined with respect to the ground of the guide vanes 2680 may be provided in a range of 90 to 150 degrees.

The guide vanes 2680 (the second portion thereof extending downwardly) may be provided with a same inclination (included) angle a with respect to the ground (with respect to the top surface of the body portion 2675 or with respect to the top surface of the spin chuck 2631). Alternatively, the guide vanes 2680 may be provided with different inclination angles a, b, and c. For example, in the five guide vanes shown in FIG. 13, the inclination angle a of second guide vane 2680 with respect to the ground (with respect to the top surface of the body portion 2675) s may be provided smaller than the inclination angle b of the third guide vane 2680 with respect to the ground (with respect to the top surface of the body portion 2675). The inclination (included) angle c of the fourth guide vane 2680 may be provided greater than the inclination angle b of the third guide vanes. The inclination (included) angle of first and fifth guide vanes is substantially 90 degrees with respect to the ground (the top surface of the body portion 2675), i.e., the second portion extending downwardly of the first and fifth guide vanes is parallel with the rotation shaft 2637.

Since the guide vane 2680 has downwardly (and optionally offset along the rotational direction of the spin chuck 2631) extending portion, the direction of the rotational airflow caused by the rotation of the spin chuck 2631 may be guided downwardly to the exhaust line 2660 to be exhausted. It is possible to minimize an upward branch airflow generated when the rotational airflow contacts the guide vane 2680. For this reason, it is possible to eliminate an airflow stagnation within the treating space.

Referring to FIG. 14, the guide vane 2680 may outwardly protrude from the body portion 2675 to be formed in a downward direction, for example, beyond the bottom end of the body portion 2675, and may be provided in a form in which a width thereof becomes narrower toward the downward direction. The top surface of the guide vane 2680 may be flushed with the top surface of the body portion 2675. In some embodiments, the guide vane 2680 may extend beyond the top surface of the body portion 2675 such that top surface of the guide vane 2680 is higher than the top surface of the body portion 2675.

The inventive concept is not limited to this, and the guide vane 2680 may be modified in shape such that the ratio of the maximum width (the width at the top end) to the length is 0.5 or greater. The inventive concept is not limited to this, and the guide vane 2680 may be modified such that the ratio of the thickness to a round value of an edge is 0.1 or greater.

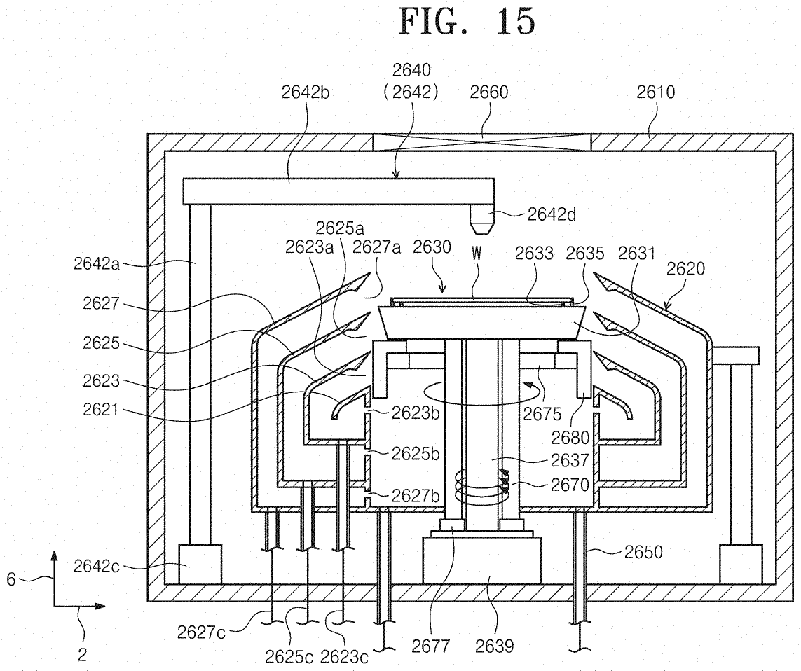

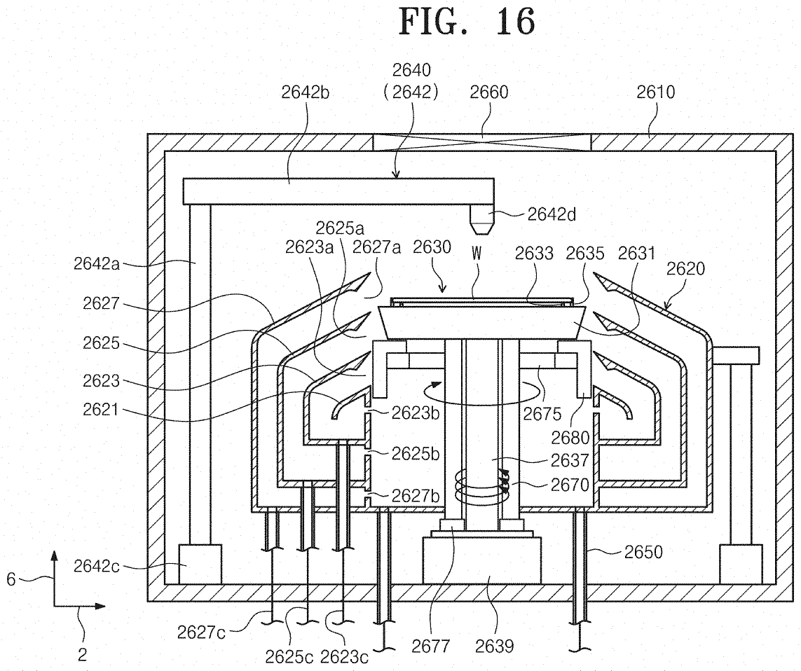

FIG. 15 to FIG. 16 schematically illustrate another embodiment of the process chamber of the substrate treating apparatus of FIG. 4. In the above exemplary embodiments, the support frame 2670 is provided to be stationary with respect to the rotation of the support unit 2630. The inventive concept, however, is not limited thereto, and the support frame 2670 may be provided to be rotatable. In the following embodiments, the housing 2610, the treating container 2620, the support unit 2630, the liquid supply unit 2640, the exhaust line 2650, and the airflow supply unit 2660 of the process chamber 260 are provided similarly to the embodiment of FIG. 4. In addition, the guide vane 2680 is provided similarly to the embodiments of FIG. 4 to FIG. 14.

Referring to FIG. 15, the support frame 2670 is disposed to surround the support unit 2630. The support frame 2670 may be provided to surround the outer circumferential surface of the rotation shaft 2637. The support frame 2670 may be provided in a ring form surrounding the outer circumferential surface of the rotation shaft. The support frame 2670 is provided independently of the rotation of the support unit 2630. The support frame 2670 may be rotated in a same direction as the rotational direction of the support unit 2630. The support frame 2670 may include a second driver 2677 that provides a rotational force in a same direction as a rotational direction of the support unit 2630. The second driver 2677 may be provided under the support frame 2670. The second driver 2677 may change a rotation speed. The rotation speed of the support frame 2670 may be provided at a speed lower than the rotation speed of the support unit 2630. The second driver 2677 may be a motor that provides a driving force. However, the inventive concept is not limited thereto, and may be variously modified as a known device that provides the driving force. As another example, gears (not shown) may be coupled to and between the inner circumferential surface of the support frame 2670 and the outer circumferential surface of the support unit 2630. A gear (not shown) provided on the inner circumferential surface of the support frame 2670 may have a larger diameter than a gear provided on the outer circumferential surface of the support unit 2630. Accordingly, the support frame 2670 may rotate in the same direction as the rotational direction of the support unit 2630 and at a speed lower than the rotation speed of the support unit 2630. The inventive concept is not limited thereto, and as shown in FIG. 16, the support frame 2670 and the support unit 2630 may rotate in opposite directions.

In the embodiments described with reference to FIG. 4 to FIG. 16, the guide vanes 2680 are coupled to the support frame 2670 or the body portion 2675 thereof. In other words, it may be referred that the guide vane 2680 is indirectly mounted on the support unit 2630 via the body portion 2675. The inventive concept is not limited thereto, and the guide vane 2680 may be provided directly mounted on the support unit 2630.

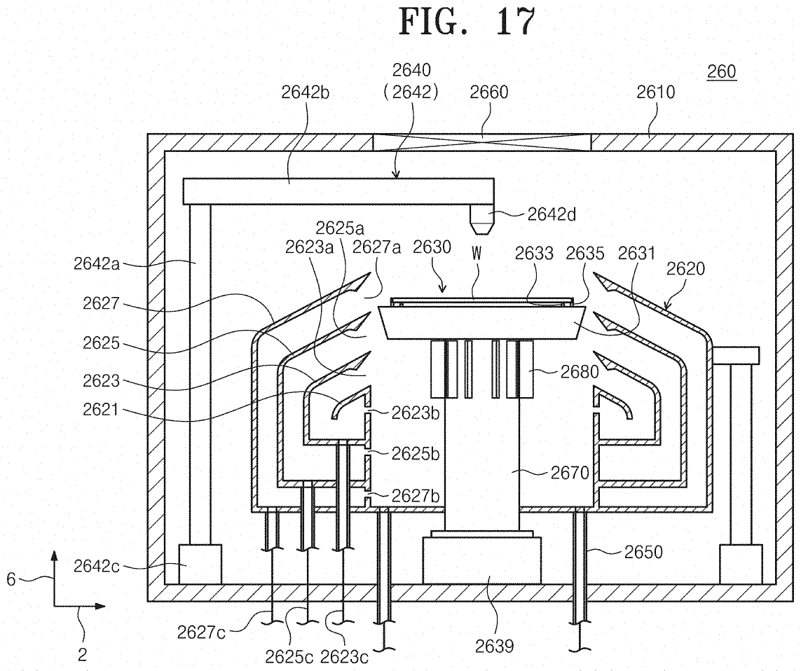

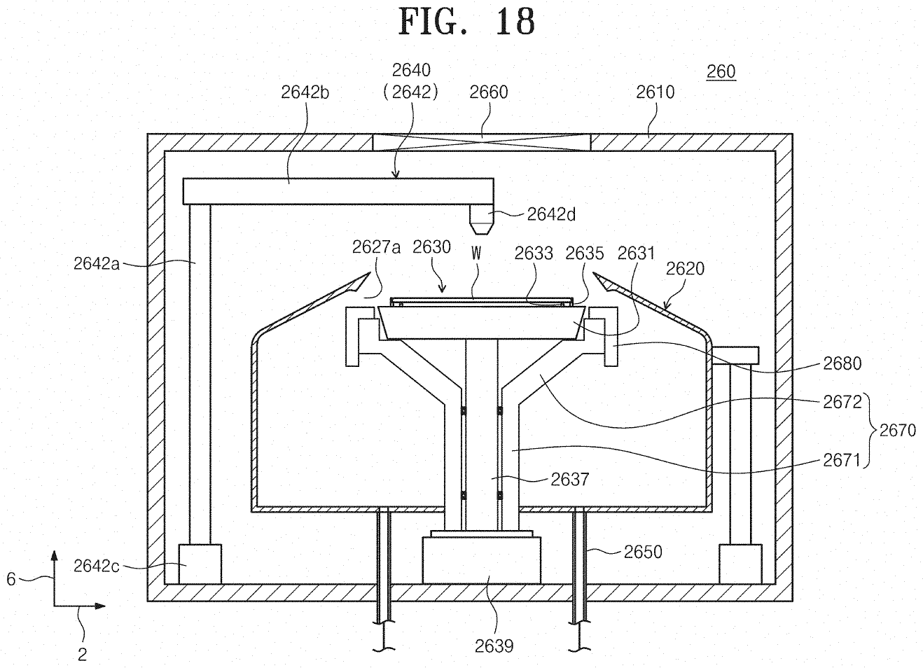

FIG. 17 to FIG. 18 schematically illustrate another embodiment of the process chamber of the substrate treating apparatus of FIG. 4. In the following embodiments, the housing 2610, the treating container 2620, the support unit 2630, the liquid supply unit 2640, the exhaust line 2650, and the airflow supply unit 2660 of the process chamber 260 are provided similarly to the embodiment of FIG. 4.

Referring to FIG. 17, the support frame 2670 is disposed to surround the support unit 2630. The support frame 2670 may be provided to surround the outer circumferential surface of the rotation shaft 2637. The support frame 2670 may be provided in a ring form surrounding the outer circumferential surface of the rotation shaft. The support frame 2670 is provided independently of the rotation of the support unit 2630. In an embodiment, a bearing may be provided between the inner circumferential surface of the support frame 2670 and the outer circumferential surface of the rotation shaft 2637. Accordingly, the support frame 2670 may be provided to be stationary with respect to the rotation of the support unit 2630. This invention is not limited to this, and as described in FIG. 15 to FIG. 16, the support frame 2670 may rotate independently from the rotation of the support unit 2630.

The guide vane 2680 is mounted on the support frame 2670. The guide vane 2680 may be directly mounted on the support frame 2670. In an embodiment, the guide vane 2680 may protrude from the outer circumferential surface of the support frame 2670, and may be provided such that the lengthwise direction thereof extends downward. The guide vane 2680 may be with its lengthwise direction perpendicular to the ground. The guide vane 2680 may be provided in a plurality along the circumferential direction of the outer circumferential surface of the support frame 2670. The plurality of guide vanes 2680 may be provided to be spaced apart from each other at predetermined intervals. In addition, the plurality of guide vanes 2680 may be provided to be spaced apart from each other at different intervals. A top end of the guide vane 2680 may be provided at a position lower than a bottom surface of the spin chuck 2631. A form and an angle of the guide vane 2680 may be modified and provided as shown in FIG. 11 to FIG. 14.

Referring to FIG. 18, the support frame 2670 is provided independently from the rotation of the support unit 2630. In an embodiment, the bearing may be provided between the inner circumferential surface of the support frame 2670 and the outer circumferential surface of the rotation shaft 2637. Accordingly, the support frame 2670 may be provided to be stopped with respect to the rotation of the support unit 2630. The inventive concept is not limited to this, and as described in FIG. 15 to FIG. 16, the support frame 2670 may rotate independently from the rotation of the support unit 2630.

The support frame 2670 is disposed to surround the support unit 2630. The support frame 2670 may include a first portion 2671 and a second portion 2672. The first portion 2671 may be provided to surround the outer circumferential surface of the rotation shaft 2637. In an embodiment, the first portion 2671 may be provided in a ring form to surround the outer circumferential surface of the rotation shaft 2637. The second portion 2672 upwardly extends from the first portion 2671. The second portion 2672 may be provided to surround the outer circumferential surface of the spin chuck 2631. The second portion 2672 may be provided to be upwardly and outwardly extending from the first portion 2671.

The guide vane 2680 is mounted on a top end of the second portion 2672. The guide vane 2680 may be coupled to the top surface of the second portion 2672 and extends downwardly along top side of the second portion 2672. The guide vane 2680 may be provided with its lengthwise direction perpendicular to the ground. In addition, the guide vane 2680 may be provided such that its lengthwise direction is inclined with respect to the ground. The plurality of guide vanes 2680 may be provided in the circumferential direction of the second portion 2672. The plurality of guide vanes 2680 may be provided to be spaced apart from each other at predetermined intervals. In addition, the plurality of guide vanes 2680 may be provided to be spaced apart from each other at different intervals. A top end of the vane 2680 may be provided at a position higher than the bottom surface of the spin chuck 2631 and lower than the top surface of the spin chuck 2631. The inventive concept is not limited thereto, and the top end of the guide vane 2680 may be provided at a position lower than the bottom surface of the spin chuck 2681. The guide vane 2680 is formed at the second portion 2672 surrounding the outer circumferential surface of the spin chuck 2631 to guide the rotational airflow formed on the side surface of the spin chuck 2631 in the downward direction.

In the embodiments, it has been described that the guide vane 2680 is directly mounted on the top surface of the second portion 2672. The guide vane 2680 is not limited thereto, and may be indirectly mounted on the second portion 2672 via the body portion 2675 as shown in the embodiment of FIG. 9 to FIG. 15. In addition, the shape and the angle of the guide vane 2680 may be modified and provided as shown in FIG. 11 to FIG. 14.

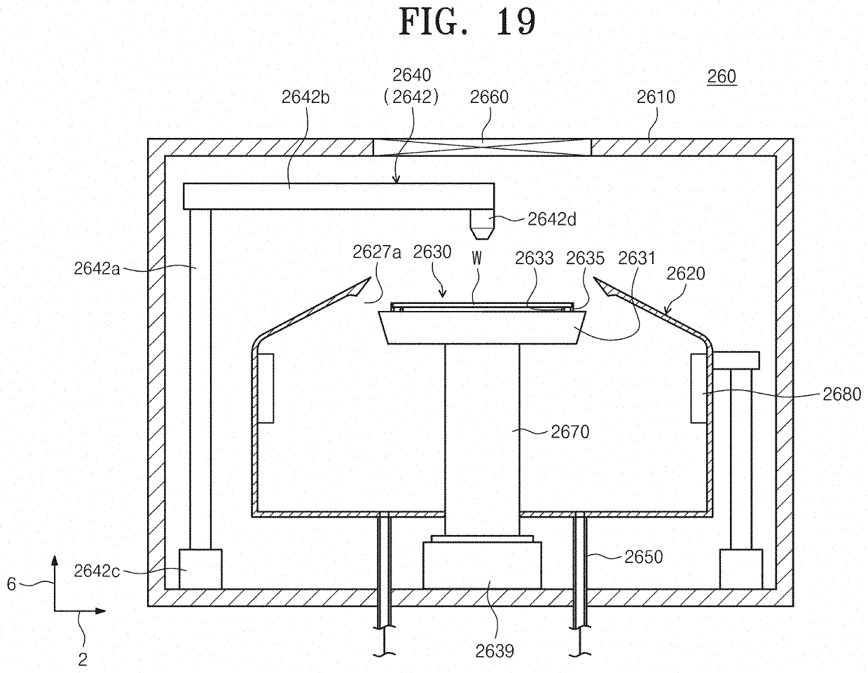

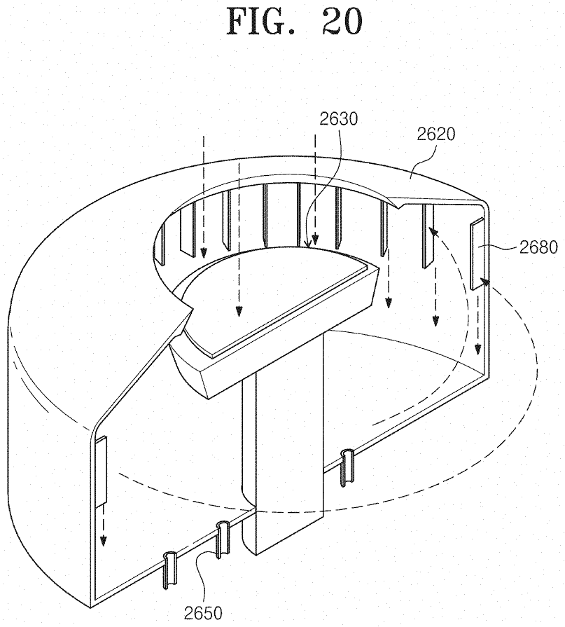

FIG. 19 schematically illustrates another embodiment of the process chamber of the substrate treating apparatus of FIG. 4. FIG. 20 is a cutting perspective view schematically illustrating the airflow in the treating container of FIG. 19.

In the following embodiments, the housing 2610, the support unit 2630, the liquid supply unit 2640, the exhaust line 2650, the airflow supply unit 2660, and the guide vane 2680 of the process chamber 260 are provided similarly to the embodiment of FIG. 4.

Referring to FIG. 19 and FIG. 20, the treating container 2620 has a treating space with an open top. The substrate W is liquid-treated within the treating space. According to an embodiment, the treating container 2620 recollects the liquid used for treating the substrate. The treating container 2620 is provided in an annular ring form surrounding the support unit 2630.

The guide vane 2680 may be directly mounted on an inner wall of the treating container 2620. In addition, the guide vane 2680 may be indirectly mounted on the inner wall of the treating container 2620 via a body portion 2675 formed in an annular ring shape. Since the detailed shape of the guide vane 2680 or the like is provided similarly to other embodiments described above, a description thereof will be omitted below.

The rotational airflow formed by the rotation of the support unit 2630 may be guided downwardly by the guide vane 2680 mounted directly or indirectly on the inner wall of the recollecting container 2623. The airflow guided downwardly is discharged to the exhaust line 2650. For this reason, an airflow exhaust inside the treating space may be smoothly provided. (treating container)

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a treating container having a treating space;
a support unit configured to support and rotate a substrate in the treating space;
an exhaust line coupled to the treating container to exhaust an airflow within the treating space;
a support frame provided independently of a rotation of the support unit and positioned between the treating container and the support unit; and
a guide vane protruding to an outside of the support frame and configured to guide the airflow within the treating space in a downward direction.

2. The substrate treating apparatus of claim 1, wherein the support unit comprises:
a spin chuck supporting the substrate;
a rotation shaft coupled to a bottom surface of the spin chuck and configured to rotate the spin chuck; and
a first driver configured to provide a rotational force to the rotation shaft, and
wherein the support frame has a ring shape to surround an outer circumferential surface of the rotation shaft.

3. The substrate treating apparatus of claim 2, wherein the guide vane includes a longitudinally extending portion defining a substantially 90 degrees included angle with a top surface of the spin chuck.

4. The substrate treating apparatus of claim 2, wherein the guide vane includes a longitudinally extending portion defining an obtuse included angle with a top surface of the spin chuck.

5. The substrate treating apparatus of claim 2, wherein the guide vane is provided in a plurality along on an outer circumferential surface of the support frame, and each of the plurality of the guide vanes includes a longitudinally extending portion, at least two of the plurality of the guide vanes having different included angles with a top surface of the spin chuck each other.

6. The substrate treating apparatus of claim 2, wherein the guide vane further includes a transversely extending portion from the longitudinally extending portion along a top surface of the support frame, the transversely extending portion has a top surface lower than the bottom surface of the spin chuck.

7. The substrate treating apparatus of claim 2, wherein the guide vane further includes a transversely extending portion from the longitudinally extending portion along a top surface of the support frame, the transversely extending portion has a top surface lower than the top surface of the spin chuck and higher than the bottom surface of the spin chuck.

8. The substrate treating apparatus of claim 1, wherein the support frame is stationary within the treating container.

9. The substrate treating apparatus of claim 1, wherein the support frame further comprises a second driver configured to rotate the support frame independently of the rotation of the support unit, and
wherein the second driver rotates the support frame in the same direction with and at a lower speed than of the support unit.

10. The substrate treating apparatus of claim 1, wherein the support frame further comprises a second driver configured to rotate the support frame independently of the rotation of the support unit, and
wherein the second driver rotates the support frame in the opposite direction to the support unit.

11. A substrate treating apparatus of claim 2, wherein the support frame further comprises an annular ring body adjacent a bottom of the spin chuck and having substantially planar top and bottom surfaces, and
wherein the guide vane includes a first portion transversely extending along the top surface of annular ring body and a second portion longitudinally extending from the first portion at least along outer sidewall of the annular ring body.

12. The substrate treating apparatus of claim 11 further comprises a rear nozzle on the top surface of the annular ring body to discharge a liquid to the spin chuck.

13. A substrate treating apparatus comprising:
a treating container having a treating space;
a support unit configured to support and rotate a substrate in the treating space;
an exhaust line coupled to the treating container to exhaust an airflow within the treating space; and
a guide vane configured to guide an airflow within the treating space in a downward direction.

14. The substrate treating apparatus of claim 13, wherein the guide vane extends longitudinally in parallel with a rotation axis of the support unit.

15. The substrate treating apparatus of claim 13, wherein the guide vane extends longitudinally with defining an acute included angle with a rotation axis of the support unit.

16. The substrate treating apparatus of claim 13 further comprises a support frame provided independently of the rotation of the support unit and surrounding the support unit, and
wherein the guide vane is mounted on the support frame.

17. The substrate treating apparatus of claim 13, wherein the guide vane is installed on an inner wall of the treating container.

18. A substrate treating apparatus comprising:
a housing having an inner space;
a treating container disposed within the inner space and having a treating space;
a support unit configured to support and rotate a substrate in the treating space;
a liquid supply unit configured to supply a liquid to the substrate supported by the support unit;
an airflow supply unit forming an airflow in the treating space;
an exhaust line coupled to the treating container to exhaust an airflow within the treating space;
a stationary support frame provided independently of a rotation of the support unit and positioned between the treating container and the support unit; and
a guide vane installed on the support frame and configured to guide the airflow within the treating space in a downward direction.

19. The substrate treating apparatus of claim 18, wherein the guide vane extends downwardly in substantially parallel with a rotation axis of the support unit.

20. The substrate treating apparatus of claim 18, wherein the guide vane extends downwardly with defining an acute included angle with a rotation axis of the support unit.
